(19) United States
(12) Patent Application Publication
(10) Pub. No.: US 2010/0140600 A1
(43) Pub. Date: Jun. 10, 2010

(54) THIN FILM TRANSISTORS INCORPORATING INTERFACIAL CONDUCTIVE CLUSTERS

(75) Inventors: Robert S. Clough, St. Paul, MN (US); Tzu-Chen Lee, Woodbury, MN (US); Dennis E. Vogel, Lake Elmo, MN (US); Peiwang Zhu, Woodbury, MN (US)

Correspondence Address: 3M INNOVATIVE PROPERTIES COMPANY, PO BOX 33427, ST. PAUL, MN, 55133-3427, US

(73) Assignee: 3M INNOVATIVE PROPERTIES COMPANY, St. Paul, MN (US)

(21) Appl. No.: 12/596,164

(22) PCT Filed: May 13, 2008
(86) PCT No.: PCT/US2008/063511

§ 371 Date: Oct. 16, 2009

Related U.S. Application Data
(60) Provisional application No. 60/946,780, filed on Jun. 28, 2007.

(51) Int. Cl. H01L 51/10; H01L 51/40

(52) U.S. Cl. 257/40; 438/99; 257/E51.006; 257/E51.027

(57) ABSTRACT

A field effect transistor includes a thin layer of discontinuous conductive clusters between the gate dielectric and the active layer. The active layer can include an organic semiconductor or a blend of organic semiconductor and polymer. Metals, metal oxides, predominantly non-carbon metallic materials, and/or carbon nanotubes may be used to form the layer of conductive clusters. The conductive clusters improve transistor performance and also facilitate transistor fabrication.

### TECHNICAL FIELD

The present invention is related to thin film transistors and approaches for fabricating thin film transistors.

### BACKGROUND

Thin film transistors (TFTs), particularly those made of organic semiconductor materials, are of interest for use in flat panel displays and in many other applications. For example, flat panel displays based on organic TFTs can have lower fabrication costs when compared to TFTs fabricated using inorganic materials. Organic-based transistors have the potential to allow fabrication of large area displays and other devices that provide both high performance and low cost. However, at the present time, devices made with inorganic components significantly outperform their organic-based counterparts.

Among currently used materials for fabrication of TFTs, small molecule and solution-based polymeric organic materials are of particular interest. Typically, small molecule organic materials have low solubility in organic solvents and thus fabrication of useful TFTs requires relatively expensive manufacturing processes, such as vacuum deposition and/or photolithography. Solution-based organic transistors cost less to fabricate because they are amenable to processing using inexpensive coating and patterning techniques. Thus, solution-based organic TFTs provide an attractive option for use in large area or disposable devices.

Improved performance and fabrication processes for organic or inorganic thin film transistors are desirable. The present invention fulfils these and other needs, and offers other advantages over the prior art.

### SUMMARY

Embodiments of the invention are directed to thin film transistors and approaches for fabricating thin film transistors. One embodiment is directed to a thin film field effect transistor. The transistor includes an active layer comprising a semiconductor. Gate, source, and drain contacts are electrically coupled to the active layer. A gate dielectric is arranged in relation to the gate contact. A layer of discontinuous conductive clusters is arranged between the gate dielectric and the active layer.

Another embodiment of the invention is directed to a thin film field effect transistor having an active layer comprising a semiconductor material and carbon nanotubes. Gate, source, and drain contacts are electrically coupled to the active layer. A dielectric material is arranged relative to the gate contact. A layer of discontinuous conductive material is arranged between the dielectric material and the active layer.

A further embodiment of the invention involves a method for fabricating thin film transistors having gate, source and drain contacts. An active layer comprising a semiconductor is formed. A dielectric layer is formed between the active layer and the gate contact of the transistor. A layer of discontinuous conductive clusters is formed between the dielectric and the active layer.

The above summary of the present invention is not intended to describe each embodiment or every implementation of the present invention. Advantages and attainments, together with a more complete understanding of the invention, will become apparent and appreciated by referring to the following detailed description and claims taken in conjunction with the accompanying drawings.

### DESCRIPTION OF THE DRAWINGS

FIG. 1 illustrates a TFT structure absent the active layer, the TFT structure having a layer of discontinuous conductive clusters in accordance with embodiments of the invention;

FIGS. 2A-2C illustrate cross sectional views of various TFT configurations that incorporate interfacial conductive clusters in accordance with various embodiments;

FIG. 3 is a flow diagram of a process for fabricating TFTs in accordance with embodiments of the invention;

FIG. 4 illustrates a cross sectional view of a TFT incorporating interfacial conductive clusters and having carbon nanotubes dispersed in the active layer in accordance with embodiments of the invention;

FIG. 5 is an atomic force microscope image of the surface of a layer of discontinuous conductive clusters in accordance with embodiments of the invention;

FIG. 6 is the step height plot of the surface of FIG. 5;

FIGS. 7A and 7B are characteristic plots of TFTs fabricated using various organic semiconductor formulations with and without gold clusters at the dielectric-semiconductor interface that illustrate the improved carrier mobility of TFTs having interfacial gold clusters in accordance with embodiments of the invention;

FIGS. 8A and 8B, respectively, show characteristic plots of TFTs fabricated with and without interfacial gold clusters illustrating the repeatability of TFTs having interfacial gold clusters in accordance with embodiments of the invention;

FIGS. 9A and 9B are characteristic plots of TFTs fabricated with interfacial gold clusters illustrating the effect of the interfacial layer on channel length in accordance with embodiments of the invention;

FIG. 10 shows three separate scans of characteristic plots of a TFT fabricated using carbon nanotubes dispersed in the active layer but without an interfacial layer of conductive clusters; and

FIGS. 11 and 12 show characteristic plots of TFTs fabricated using carbon nanotubes dispersed in the active layer and also having an interfacial layer of conductive clusters in accordance with embodiments of the invention.

While the invention is amenable to various modifications and alternative forms, specifics thereof have been shown by way of example in the drawings and will be described in detail. It is to be understood, however, that the intention is not to limit the invention to the particular embodiments described. On the contrary, the intention is to cover all modifications, equivalents, and alternatives falling within the scope of the invention as defined by the appended claims.

### DETAILED DESCRIPTION

In the following description of the illustrated embodiments, reference is made to the accompanying drawings that form a part hereof, and in which are shown by way of illustration, various embodiments in which the invention may be practiced. It is to be understood that the embodiments may be utilized and structural changes may be made without departing from the scope of the present invention.

Organic-based thin film transistors provide a relatively low-cost option for fabrication of disposable and/or large area electronic devices. Several types of semiconductors are presently used for making electronic devices. Small molecule organic semiconductors and solution-based polymeric organic semiconductors are two examples. Typically, small molecule organics have low solubility in organic solvents and thus require vacuum deposition or other relatively expensive techniques to form films. Shadow mask or photolithographic methods are used to pattern multiple layers to make useful devices. Vacuum deposition, shadow mask, and photolithography are relatively more expensive fabrication processes when compared to processes available for the solution-based polymeric semiconductors.

Solution-based organic TFTs have the potential to allow the lowest fabrication cost among organic semiconductor types because devices can be formed using less expensive coating and patterning processes. For example, deposition of the films may be accomplished by spin coating, knife-coating, roll-to-roll web-coating, dip coating, and other techniques. The solution-based organic devices can be patterned by ink-jet printing, gravure printing, or screen printing, for example.

The performance of solution-based organic transistors is usually lower than vacuum deposited small-molecule-based transistors. It is desirable to improve the performance of TFTs of all types, particularly organic TFTs having the potential to provide low cost electronic devices.

The effect of lower carrier mobility exhibited by organic semiconductor materials, in particular solution-based organics, is exacerbated when coupled with inexpensive TFT fabrication methods, such as printing processes. The limited feature size resolution of some inexpensive patterning processes can preclude fabrication of electronic devices with a sufficiently short channel to provide a useful device. For example, the feature size resolution of some processes may be greater than 20 microns. Thus, it is desirable to develop structures that compensate for the relatively longer channel produced by inexpensive fabrication processes.

Embodiments of the invention are directed to approaches that enhance organic or inorganic TFT performance, particularly the performance of organic TFTs, including solution-based organic TFTs. The techniques described herein produce solution-based organic TFTs that have comparable performance to organic TFTs formed using vacuum-deposited small-molecule materials.

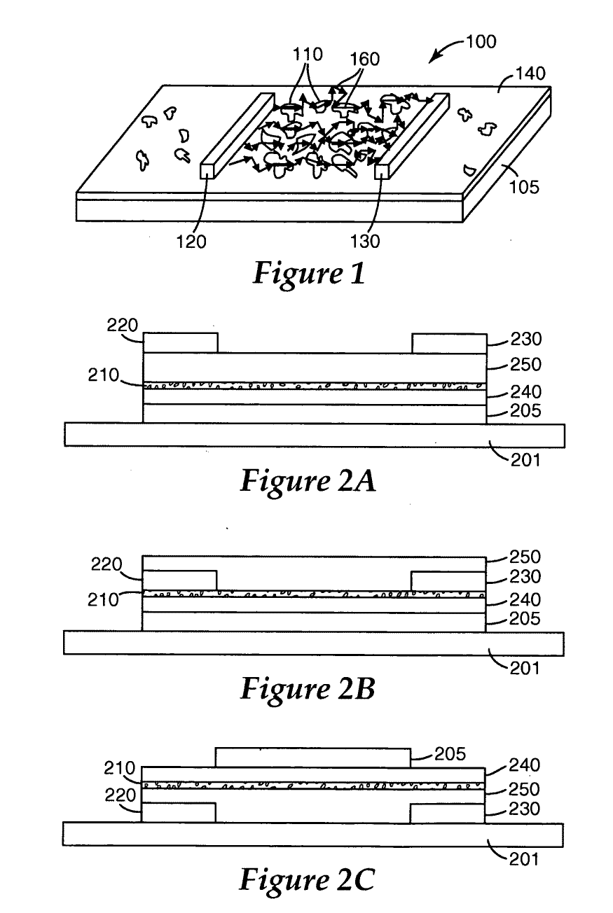

Embodiments of the invention are directed to TFT devices that include a layer of 2-D discontinuous electrically conductive clusters or islands at the interface between the gate dielectric and the active layer. The 2-D discontinuous conductive clusters can also be present in the active layer or on top of the active layer or in the gate dielectric. The transistor structure 100 of FIG. 1 illustrates a TFT structure absent the active layer. The transistor structure 100 includes gate, source, and drain electrodes 105, 120, 130. A thin layer of discontinuous conductive clusters 110 is disposed on the gate dielectric 140 at the interface between the gate dielectric 140 and the active layer (not shown in FIG. 1).

While not bound by any particular theory, one explanation for the performance of TFTs constructed with interfacial conductive clusters is that the layer of conductive clusters 110 modifies the transport mechanism of the carriers in the channel region of the TFT. The thin layer of conductive clusters 110 allows some of the carriers in the TFT channel region near the dielectric-semiconductor interface to flow ballistically for a portion of their path across the channel. Arrows 160, indicate the path of carriers that flow ballistically within the conductive clusters 110. Carriers that flow ballistically in this manner avoid the relatively slower transport processes through the semiconductor active layer that involve hopping and scattering in molecules. The presence of conductive clusters 110 in the channel region between the dielectric 140 and the semiconductor layer effectively reduces the channel length, increases carrier mobility, and increases transconductance of the TFT. The conductive clusters 110 may also serve to reduce the charge trapping process in the semiconductor material of the active layer.

FIGS. 2A-2C illustrate cross sectional views of various TFT configurations that incorporate interfacial conductive clusters in accordance with various embodiments. FIG. 2A illustrates a configuration having top source and drain contacts 220, 230 and a bottom gate contact 205 disposed on a substrate 201. The thin layer of discontinuous conductive clusters 210 is arranged between the gate dielectric 240 and the active layer 250.

The configuration illustrated in FIG. 2B is similar to the configuration discussed in connection with FIG. 1 above. In this configuration, the source and drain contacts 220, 230 are arranged at least partially beneath the active layer 250. The gate contact 205 is disposed on a substrate 201. The interfacial layer of conductive clusters 210 is between the active layer 250 and the dielectric 240.

FIG. 2C illustrates yet another TFT configuration in accordance with embodiments of the invention. The configuration illustrated in FIG. 2C has source 220 and drain 230 contacts disposed on a substrate 201. The active layer 250 is disposed over the source 220 and drain 230 contacts. The interfacial layer of conductive clusters 210 is arranged between the gate dielectric 240 and the active layer 250. A gate contact 205 is disposed on the dielectric 240.

FIGS. 2A-2C provide a few illustrative examples of TFT configurations incorporating an interfacial layer of conductive clusters. Many other configurations are also possible.

The addition of a layer of conductive clusters at the dielectric/semiconductor interface to enhance device properties is counterintuitive because the presence of impurities at the semiconductor junction is known to degrade junction characteristics in other transistor technologies. For example, impurities at the gate-semiconductor junction are known to increase leakage current and degrade the ON/OFF current ratio. However, without being bound to theory, particularly in the case of solution-based organic TFTs, the thin interfacial layer of conductive clusters appears to make the overall carrier transport process more efficient, thus improving transistor characteristics. The improvement in carrier mobility is most pronounced in solution-based polymeric semiconductors, presumably because these semiconductor materials have a relatively low carrier mobility which can be improved significantly by the addition of the conductive clusters.

Furthermore, conductive clusters at the gate dielectric-active layer interface unexpectedly alter the wetting properties of the semiconductor on the dielectric film. The presence of the thin layer of conductive clusters significantly improves contact between the dielectric film and the semiconductor material during fabrication of the TFTs. In addition, TFTs having the conductive cluster interface layer showed enhanced repeatability when sequential scans of drain current (I_{d}) vs. gate voltage (V_{g}) were conducted. The threshold voltage was more repeatable in TFTs having a layer of conductive clusters when compared with TFTs without the conductive cluster layer.

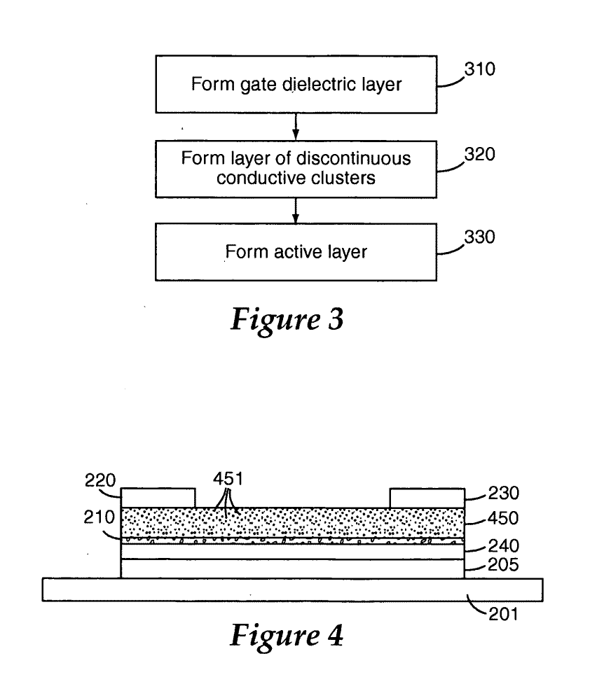

FIG. 3 is a flow diagram of a process for fabricating TFTs in accordance with embodiments of the invention. The steps of the process do not need to be performed in any particular order. A gate dielectric is formed 310. A thin layer of conductive clusters is formed 320 proximate to the gate dielectric film. The thickness of the conductive cluster layer is sufficiently thin so that no continuous conducting paths across the device channel are formed. The active layer is formed 330 proximate to the conductive cluster layer.

One example of TFT formation involves the formation of the gate metallization electrode, followed by formation of the gate dielectric film on the gate metallization electrode. An ultra-thin layer of predominantly non-carbon metallic clusters is formed on a gate dielectric film. An active layer comprising an organic semiconductor is coated or printed on the metallic cluster surface, followed by the formation of source and drain electrodes to form top-contact TFTs.

Processes and structures that use a thin layer of discontinuous conductive clusters at the dielectric-semiconductor interface are especially compatible with low cost patterning methods, such as printing processes, that have limited resolution. The layer of conductive clusters can effectively shorten the channel length from the physically long channel length produced by printing. Therefore, the use of a thin layer of conductive clusters at the dielectric-semiconductor interface at least partially compensates for the lower resolution of inexpensive patterning methods.

The active layer, which may include one or more material layers, comprises an organic semiconductor, such as a small molecule organic semiconductor or solution-based organic semiconductor or a blend of organic semiconductor and a polymer or inorganic semiconductors. In one embodiment, the active layer may comprise a low molecular weight organic semiconductor. In another embodiment, the active layer may comprise a polymeric organic semiconductor. In another embodiment, the active layer may include a blend of an organic semiconductor and a polymer.

In some embodiments, carbon nanotubes are dispersed in the semiconductor material or semiconductor and polymer blended material to form non-continuous, 3-D conducting paths in the active layer. Several examples of suitable materials for the active layer are provided in more detail below.

There are many options for selecting materials for the conductive clusters, which may comprise predominantly non-carbon metallic materials, metals or metal oxides, for example. The selection of the cluster material preferably takes into account the type of semiconductor used to form the active layer. It is desirable to form an ohmic contact between the conductive cluster and the organic semiconductor. For example, for p-type semiconductors, selection of the cluster material can be made from high work function materials, such as gold, palladium, platinum, etc. For n-type semiconductors, selection may be made from low work function materials, such as aluminum, silver, calcium, etc. The cluster material may comprise carbon nanotubes (CNTs). A very dilute CNT dispersion with or without the electrically conductive clusters can be coated on a surface to form discontinuous conducting paths. The work function of CNTs allows formation of an ohmic contact with most of the p-type organic semiconductors.

In some embodiments the interfacial layer of conductive clusters may include multiple sub-layers. For example, an interfacial layer may include a first sub-layer of a first material and a second sub-layer of a second material. The material, characteristics and/or physical dimensions of the clusters of the sub-layers may be the same, or the clusters of one sub-layer may have materials, characteristics and/or dimensions that differ from the materials, characteristics and/or dimensions of the clusters of another sub-layer.

As previously discussed, TFTs having interfacial conductive clusters exhibit better repeatability when sequential scans of I_{d} vs. V_{g} are conducted. The threshold voltage varies less for TFTs containing conductive clusters than for TFTs without the conductive clusters. In addition, higher carrier mobility and ON/OFF current ratio can be obtained for TFTs containing conductive clusters when compared with their counterparts without conductive clusters.

Some embodiments of the invention employ an interfacial layer of conductive clusters along with carbon nanotubes dispersed in the semiconductor material. The TFT configuration illustrated in FIG. 4 is similar to the configuration of FIG. 2A, except that carbon nanotubes 451 are dispersed in the active layer 450. For example, a low percentage of single-walled carbon nanotubes (SWCNTs) can be dispersed into a soluble TIPS pentacene (pentacene substituted with (trialkylsilyl)ethynyl groups such as pentacene substituted with two (triisopropylsilyl)ethynyl groups) or polythiophene semiconductor matrix which forms the active layer of TFTs. Inclusion of SWCNTs in the semiconductor matrix demonstrates a significant increase of the effective carrier mobility with a minor decrease of the ON/OFF current ratio. The amount of SWCNTs in the organic semiconductor matrix should be below the percolation threshold to prevent the formation of 3-dimensional conducting paths in the matrix. TFTs incorporating SWCNTs and an interfacial layer of conductive clusters between the gate dielectric and the active layer having configurations similar to FIGS. 2B and 2C, or other configurations, may also be constructed.

Without being bound by any particular theory, a partial conducting network via the metallic portion of SWCNTs in a semiconductor matrix effectively reduces the channel length between source and drain because carriers are able to flow ballistically through SWCNTs, without going through the typical hopping/scattering transport processes as in an organic semiconductor without the SWCNTs. Therefore, the inclusion of SWCNTs in the active layer effectively increases carrier mobility and transconductance of the TFT.

The operating parameters of TFTs that incorporate dispersed SWCNTs may be enhanced through control of the material composition of the active layer. The distribution of the SWCNT lengths in SWCNTs purchased from commercial suppliers is very broad. The loading percentage of SWCNTs incorporated into the matrix may vary based on the characteristics of the SWCNTs obtained. The SWCNTs should be well-dispersed in the organic semiconductor matrix. Bundles of SWCNTs in the matrix can deteriorate TFT performance.

Dispersion of even a minimal percentage of SWCNTs into an organic semiconductor active layer matrix, often produces a blended solution that cannot wet the dielectric substrate. Wetting the dielectric substrate is necessary for deposition of the active layer to form a transistor. The inclusion of a thin layer of conductive clusters, e.g., a layer having a thickness of about 10 Å or about 5 Å, at the dielectric-active layer interface can dramatically improve the wetting of the blended SWCNT/organic semiconductor solution and result in a high yield of TFTs. The combination of an interfacial layer of conductive clusters and a blended active layer material including SWCNTs in the organic semiconductor solution produces a high yield of robust organic TFTs. Solution-based top contact TFTs have shown carrier mobility greater than 1.3 cm²/V·s, ON/OFF current ratio of greater than 7×10³ and drain current greater than 10⁻⁴ amps.

As previously discussed, the incorporation of an interfacial layer of dispersed conductive clusters improves the carrier mobility and transconductance of organic-based TFTs with or without SWCNTs. In addition, higher ON/OFF current ratio and better stability of threshold voltage at repeatable scanning of source drain current vs. gate voltage have been observed. A beneficial by-product of inserting the metallic clusters on the dielectric layer is an improvement in wetting characteristics for the subsequent coating of the semiconductor solution. Because of the cluster nature of the interfacial layer, no continuous conducting paths are formed by the clusters in a two-dimensional space. By controlling the thickness of the metallic layer, and thus the size and density of the clusters, the leakage current can be reduced.

Fabrication of TFTs using an interfacial layer of conductive clusters and an active layer that does not include carbon nanotubes has certain advantages. For example, SWCNTs are expensive and their dimensions can vary from supplier to supplier, making control over the device characteristics more complex. However, the incorporation of SWCNTs in the semiconductor matrix in addition to an interfacial layer of conductive clusters at the dielectric-semiconductor interface further improves device performance. For example, solution-based top contact TFTs using both the interfacial layer along with SWCNT dispersed in the semiconductor layer have shown enhanced mobility ON/OFF current ratio and drain current.

### EXAMPLES

For TFTs without SWCNTs, three kinds of p-type organic semiconductors, designated herein as Å, B, and C, were tested on substrates having 5 Å or 10 Å gold clusters that were vacuum deposited on hexamethyldisilazane (HMDS) treated SiO₂/p-Si/Al or SiO₂/n⁺-Si/Al surface and on the same substrates with only HMDS treated SiO₂/p-Si/Al surface or bare SiO₂/n⁺-Si/Al. HMDS assists in molecular ordering so that organic semiconductors may be more conductive when biased with voltage.

Each of the three types of organic semiconductor materials, A, B, and C were dissolved in dichlorobenzene (DCB). The chemical structure of the three materials is shown in the boxes below.

A. Poly(3,4-dihexylthiophene-alt-2,6-anthracene)—1.2 wt % of A dissolved in DCB

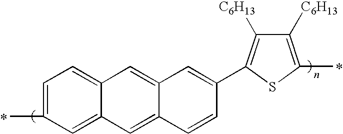

B. Poly(3,4-ethylenedioxy-2,5-thiophene-alt-9,10-bis[(triisopropylsilyl)ethynyl]-2,6-anthracene)-2 wt % of B dissolved in DCB.

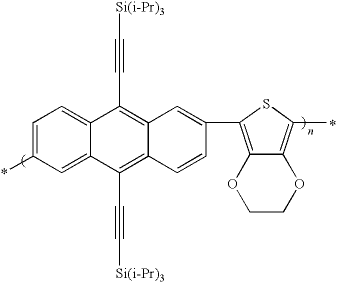

C. TIPS-pentacene—1 wt % of C and 2.5 wt % of polystyrene dissolved in DCB.

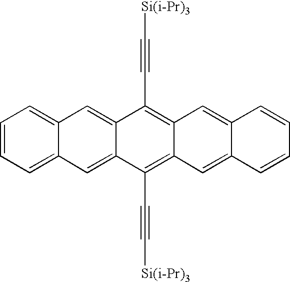

The gold clusters deposited on HMDS treated SiO₂ enhanced wet out of all three solution-based organic semiconductors. In the areas without gold clusters, wetting of the three organic solutions was either poor or would not wet the surface at all. The same effect was observed for spin coated organic semiconductors on substrates that have both gold clusters on HMDS treated SiO₂ and HMDS treated SiO₂ only.

### Example 1

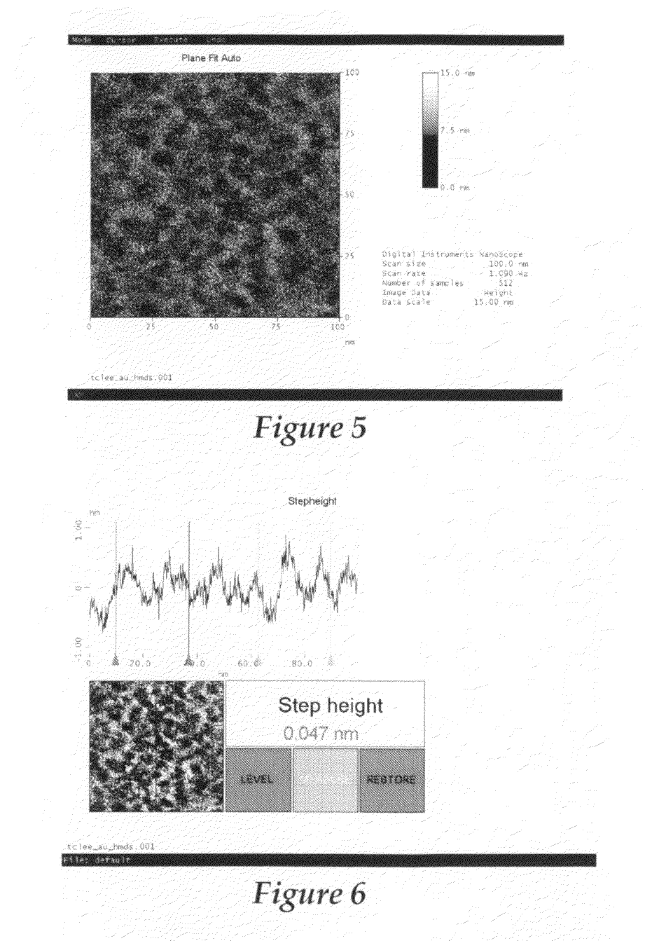

Example 1 illustrates the discontinuous configuration of the conductive clusters forming the interfacial layer. A layer of gold clusters about 10 Å thick was vacuum deposited on HMDS treated SiO₂ surface. Tapping mode was used for taking the atomic force microscope (AFM) image of this surface as shown in FIG. 5. The lighter regions in FIG. 5 are gold clusters. FIG. 5 clearly shows that the gold clusters do not form continuous conducting paths. FIG. 6 is the step height plot of the surface of FIG. 5 showing that the step height of the gold clusters is less than 2 nm.

### Example 2

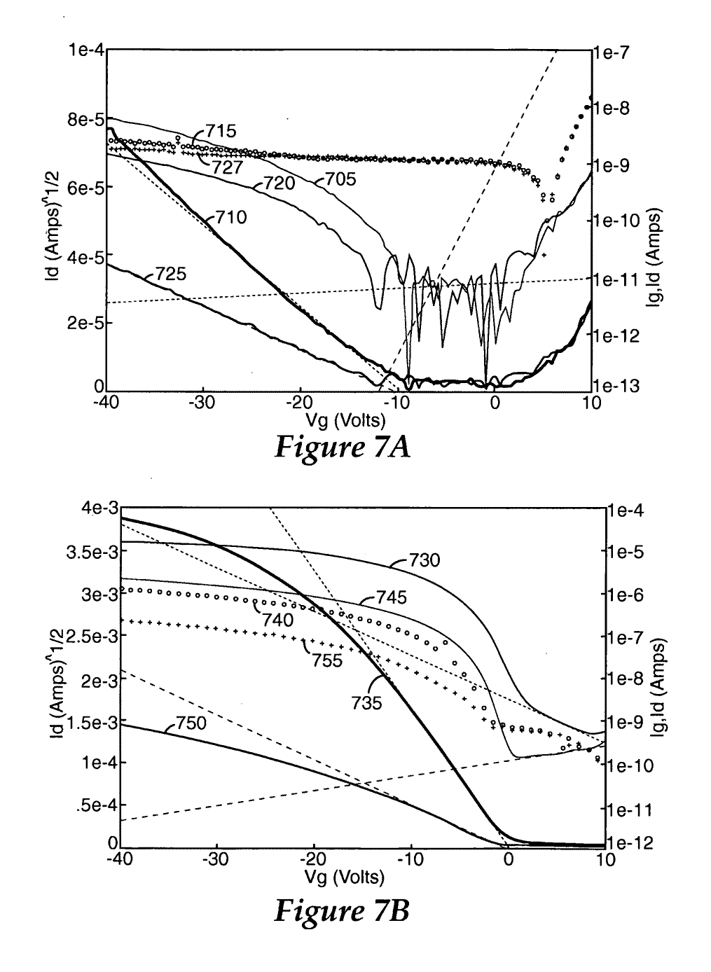

Example 2 illustrates the higher mobility of TFTs having an interfacial layer of conductive clusters when compared to similar TFTs without the interfacial layer. TFTs with the same channel width and length (W/L) made from organic semiconductor solution B with and without 10 Å of gold clusters were fabricated. FIG. 7A shows a plot 705 of the drain current (I_{d}) vs. gate voltage (V_{g}) characteristic, a plot 710 of the \sqrt{I_{d}} vs. V_{g} characteristic, and a plot of gate current (I_{g}) vs. V_{g} characteristic 715 for a TFT made from semiconductor B and containing 10 Å of gold clusters at the dielectric-semiconductor interface. FIG. 7A also shows a plot 720 of the drain current (I_{d}) vs. gate voltage (V_{g}) characteristic, a plot 725 of the \sqrt{I_{d}} vs. V_{g} characteristic, and a plot of the I_{g} vs. V_{g} characteristic 727 for a TFT made from semiconductor B without gold clusters. Analysis of these characteristics shows that the TFT with the interfacial gold clusters produces higher mobility (3.8×10⁻⁵ cm²/V·s) and ON/OFF current ratio (4.7×10⁴) than the TFT without gold clusters which has a mobility of 1.1×10⁻⁵ cm²/V·s and ON/OFF current ratio of 1.1×10⁴.

An improvement for these two parameters has also been observed for TFTs using organic semiconductor solution C as the active layer. FIG. 7B shows a plot 730 of the I_{d} vs. gate voltage V_{g} characteristic, a plot 735 of the \sqrt{I_{d}} vs. V_{g} characteristic, and a plot 740 of the I_{g} vs. V_{g} characteristic for a TFT made from semiconductor solution C and containing 5 Å of gold clusters on HMDS treated SiO₂ dielectric. FIG. 7B also shows a plot 745 of the I_{d} vs. V_{g} characteristic, a plot 750 of the \sqrt{I_{d}} vs. V_{g} characteristic, and a plot 755 of the 4 vs. V_{g} characteristic for a TFT made from semiconductor solution C on SiO₂ dielectric without the interfacial layer of gold clusters. Semiconductor C did not wet on HMDS treated SiO₂ dielectric and thus no reliable devices could be fabricated. Analysis of these characteristics shows that the TFT with the interfacial gold clusters produces higher mobility (0.17 cm²/V·s) and ON/OFF current ratio (3.1×10⁴) than the TFT without gold clusters which has a mobility of 0.02 cm²/V·s and ON/OFF current ratio of 1.6×10³.

Hole transport in the channel is via ballistic movement when the carriers enter the gold cluster regions that form an ohmic contact with the organic semiconductor. Hopping by holes among different organic molecules and scattering in the amorphous structure does not occur during the time that the carriers are in gold clusters. Thus, the size and density of the gold clusters contribute to the percentage that the travel time of the conductors can be shortened. The decrease in the travel time of the conductors can also be expressed as an effective reduction in channel length.

### Example 3

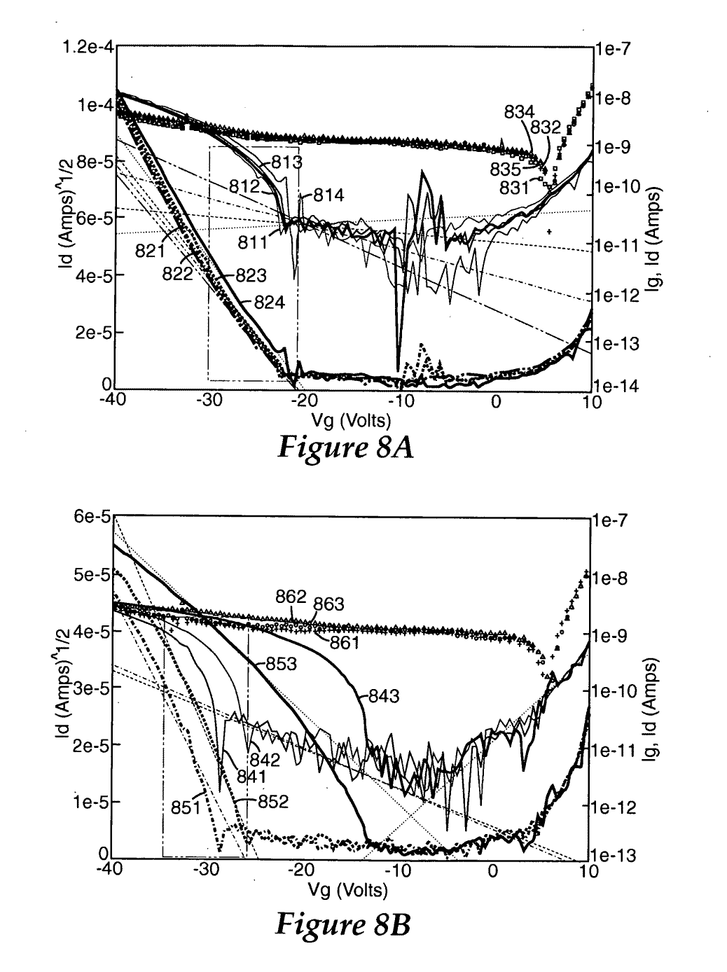

Example 3 illustrates the superior repeatability of TFTs having an interfacial layer of conductive clusters when compared to similar TFTs without the interfacial layer. A TFT was fabricated having top source and drain contacts (W/L=1120 μm/110 μm) patterned by depositing ˜800 Å of gold through a Kapton shadow mask on organic semiconductor Å which was spun on 10 Å of gold clusters deposited on HMDS treated SiO₂ surface. FIG. 8A shows I_{d} vs. V_{g} characteristics 811-814, \sqrt{I_{d}} vs. V_{g} characteristics 821-824, and I_{g} vs. V_{g} characteristics 831-834 that almost overlap each other on four separate scans without observing much shift of the threshold voltage, Vₜ, which is equal to approximately −20.6±0.5 volts.

In contrast, the same organic semiconductor solution A was spun on only HMDS treated SiO₂ surface for forming a TFT having the same W/L ratio as previously constructed but without the interfacial gold clusters. FIG. 8B shows I_{d} vs. V_{g} characteristics 841-843, \sqrt{I_{d}} vs. V_{g} characteristics 851-853, and I_{g} vs. V_{g} characteristics 861-863 in three consecutive scans for this TFT configuration. These scans reveal a large shift of the threshold voltage, from about −3.5 volts exhibited by the \sqrt{I_{d}} vs. V_{g} characteristic curve 853, to about −24.5 volts exhibited by the \sqrt{I_{d}} vs. V_{g} characteristic curve 852, to about 25.8 volts exhibited by the \sqrt{I_{d}} vs. V_{g} characteristic curve 851, where the transistor characteristics were scanned at different times.

### Example 4

Example 4 illustrates the effect of an interfacial layer of conductive clusters on channel length.

For a given thickness of the vacuum deposited ultra-thin gold on a given surface, the statistical distribution of cluster size and density is largely predetermined. There is an optimal channel length for a TFT incorporating an interfacial layer of gold clusters. As the channel length decreases, the probability for the presence of continuous, conductive paths through the deposited ultra-thin gold layer from source to drain electrode increases. If the channel length is short enough, then the TFT may have higher leakage current that results in low ON/OFF current ratio.

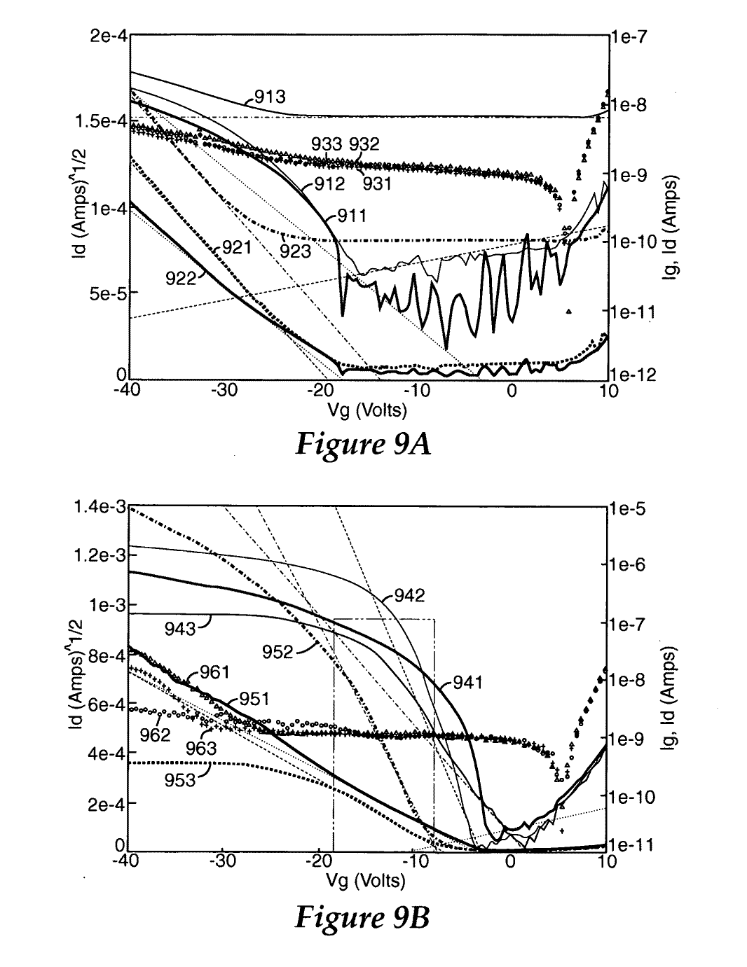

FIG. 9A shows I_{d} vs. V_{g} characteristics 911-913, I_{d} vs. V_{g} characteristics 921-923, and I_{g} vs. V_{g} characteristics 931-933 of TFTs containing gold clusters and using organic semiconductor A with three W/L ratios: 1120 μm/110 μm (plots 911, 921, 931), 500 μm/57 μm (plots 912, 922, 932), and 400 μm/47 μm (plots 913, 923, 933), respectively. At the channel length of 47 μm, the baseline of the I_{d} increased at the shorter L prior to the threshold voltage. The ON/OFF current ratio was at 3.9×10³ when L=110 μm and dropped to 4.4 at L=47 μm.

FIG. 9B shows I_{d} vs. V_{g} characteristics 941-943, \sqrt{I_{d}} vs. V_{g} characteristics 951-953, and I_{g} vs. V_{g} characteristics 961-963 of TFTs containing gold clusters and using organic semiconductor C with the three W/L ratios: 1120 μm/110 μm (plots 941, 951, 961), 500 μm/57 μm (plots 942, 952, 962), and 400 μm/47 μm (plots 943, 953, 963). The TFT having carrier mobility (3.6×10⁻² cm²/V·s) and ON/OFF current ratio (1.7×10⁵) performed the best with a channel length, L=57 μm. When L=47 μm, the ON/OFF current ratio dropped to 8.7×10³ and carrier mobility also dropped.

Examples 5 and 6 relate to TFTs having SWCNTs dispersed in the semiconductor matrix. These examples have a common type of substrate: 1,000 Å SiO₂/p-Si/Al. Boron doped p-Si, having a bulk resistivity of about 5 to 30 ohm-cm, together with about 5,000 Å of aluminum on the back side, serves as the gate electrode for TFTs. TIPS pentacene 1 wt % was dissolved in dichlorobenzene (DCB), together with 2.5 wt % of polystyrene as the basic active layer solution. The active layers for TFTs were formed using a mixture that contained 0.01 wt % SWCNTs/0.9 wt % TIPS pentacene/2.24 wt % PS in DCB which was coated on the above mentioned substrate using a knife coater.

### Example 5

Example 5 relates to TFTs with SWCNTs blended into organic semiconductor as the active layer on SiO₂.

SWCNTs were purchased from Carbon Nanotechnologies Incorporated (Houston, Tex.) with partial purification. Further purification processes were conducted to achieve more purified SWCNTs and to promote dispersion into DCB. The purification processes were as follows:

Single wall carbon nanotube (1.609 g) was suspended in nitric acid (3M, 60 mL). The suspension was refluxed at 120° C. for 4 hours. After the suspension was cooled to room temperature, SWCNTs were collected by filtration and washing with DI water until neutral. The solid was dried at 80° C. overnight and was further heated at 480° C. for 30 minutes in air. 0.961 g of black solid of SWCNTs was left after the high temperature heating to burn off amorphous carbon. The black solid of SWCNTs were then refluxed in HNO₃ (3M, 60 mL) at 120° C. for 1 hour. After being cooled to room temperature, solid was collected by filtration and washing with DI water until neutral. 0.959 g of solid was thus obtained after further drying.

0.1 wt % of these purified SWCNTs was then prepared in DCB. The solution was ultrasonically agitated for a few days before blending it with the basic active layer solution to get 0.01 wt % SWCNTs/0.9 wt % TIPS pentacene/2.24 wt % PS in DCB for forming the modified active layer.

A fabrication issue was encountered when the above solution containing even a small fraction of SWCNTs was knife-coated on SiO₂ or HMDS treated SiO₂ surface. Very poor wetting occurred when knife coating even a small fraction of SWCNTs on an SiO₂ or HMDS treated SiO₂ surface. Because of the poor wetting, a very low yield of working TFTs was obtained. Of the devices that did work, the performance was poor, as compared to TFTs without the SWCNTs.

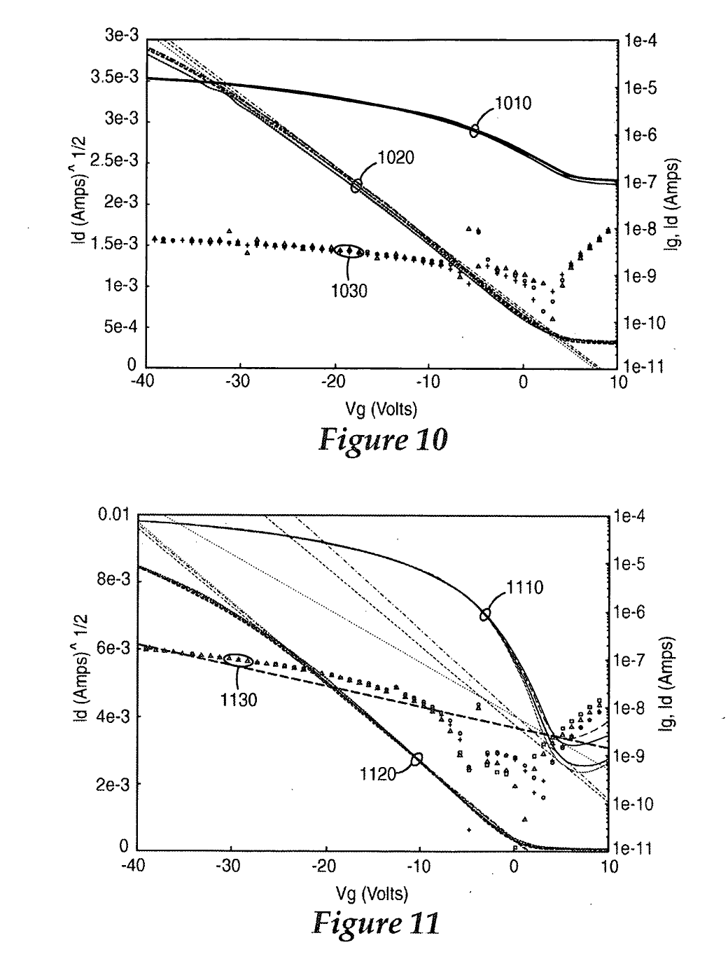

FIG. 10 shows three separate scans of the I_{d} vs. V_{g} characteristic 1010, the \sqrt{I_{d}} vs. V_{g} characteristic 1020, and the I_{g} vs. V_{g} characteristic 1030 of the TFT made from a knife-coated solution containing 0.01 wt % SWCNTs/0.9 wt % TIPS pentacene/2.24 wt % PS in DCB on a SiO₂/p-Si/Al substrate. One pronounced result from this sample is that not much shift in threshold voltage is observed by the three consecutive scans of the same TFT. However, much lower ON/OFF current ratio (about 100 or so in this example) was frequently observed, especially for short channel length TFTs (32 μm, in this example) or higher concentration of SWCNTs in the active solution.

### Example 6

In Example 6, TFTs with SWCNTs blended into organic semiconductor as the active layer and were fabricated on metallic clusters which were deposited over the gate dielectric.

The very poor wetting issue of the active solution containing even a small fraction of SWCNTs was overcome by having an ultra-thin layer of metallic cluster deposited on a bare, an HMDS treated SiO₂ surface or other polymeric gate insulator surface.

Furthermore, metallic clusters at the interface of the gate insulator and the organic semiconductor contributes additional conducting segments for transporting carriers ballistically.

Therefore, by taking advantage of 3-D and 2-D conducting paths of the SWCNTs in the organic host and metallic clusters at the interface of the gate insulator and semiconductor, respectively, TFTs exhibiting better performance were fabricated.

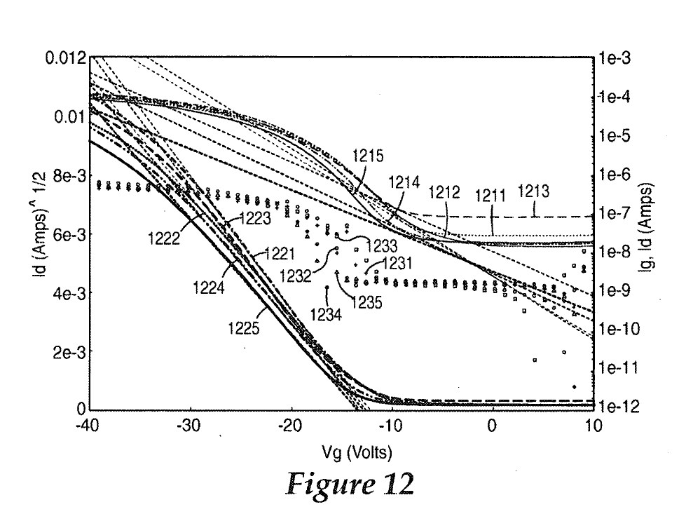

FIGS. 11 and 12 show two different such TFTs fabricated on different days. It is clear that significant improvement in performance of TFTs has been demonstrated. It also makes clear that a robust fabrication process has been developed that can produce a high yield of TFTs with high carrier mobility, low threshold voltage shift, and reasonably high ON/OFF current ratio.

FIG. 11 shows four consecutive scans of the I_{d} vs. V_{g} characteristic 1110, the \sqrt{I_{d}} vs. V_{g} characteristic 1120, and the I_{g} vs. V_{g} characteristic 1130 of a TFT with W/L=200 μm/27 μm. The TFT was fabricated by multi-pass knife-coating 0.01 wt % SWCNTs/0.9 wt % TIPS pentacene/2.24 wt % PS in DCB active solution. The substrate was 5 Å of gold clusters/HMDS treated SiO₂ by spinning at 3,000 rpm. The characteristic plots 1110, 1120, 1130 show that the TFT has mobility greater that 0.4 cm²/V·s and ON/OFF current ratio between 3×10⁴ and 1.7×10⁵. The threshold voltage shift is within 0.1 V.

There is an optimal combination of SWCNTs concentration in the active solution and the density of gold clusters for a given channel length to get a compromise of achieving higher carrier mobility and reasonably high ON/OFF current ratio.

FIG. 12 shows the I_{d} vs. V_{g} characteristics 1211-1215, the \sqrt{I_{d}}, vs. V_{g} characteristics 1221-1225, and the I_{g} vs. V_{g} characteristics 1231-1235 of five TFTs containing SWCNTs in the active layer on a sample with same W/L=500 μm/57 μm that were built on 5 Å of gold clusters/HMDS treated SiO₂. Mobility of greater than 1 cm²/V·s was achieved for all these five solution-based TFTs with ON/OFF current ratio of greater than 10³. Among the TFTs tested in this example, the highest mobility is 1.4 cm²/V·s, which is comparable to the performance of pentacene or amorphous silicon TFTs formed by vacuum deposition.

The foregoing description of the various embodiments of the invention has been presented for the purposes of illustration and description. It is not intended to be exhaustive or to limit the invention to the precise form disclosed. Many modifications and variations are possible in light of the above teaching. For example, embodiments of the present invention may be implemented in a wide variety of fabrication methods, such as using nanoparticle (gold and others) to form metallic clusters. It is intended that the scope of the invention be limited not by this detailed description, but rather by the claims appended hereto.

1. A field effect transistor, comprising:
an active layer comprising a semiconductor;
gate, source, and drain contacts electrically coupled to the active layer;
a gate dielectric arranged in relation to the gate contact; and
a layer of discontinuous interfacial conductive clusters arranged between the gate dielectric and the active layer.

2. The transistor of claim 1, wherein the layer of interfacial conductive clusters is disposed on a surface of the dielectric material.

3. The transistor of claim 1, wherein:
the field effect transistor comprises a channel; and
the layer of interfacial conductive clusters comprises a plurality of conductive regions that reduce an effective length of the channel.

4. The transistor of claim 1, wherein the active layer comprises one or more layers of a solution-based organic semiconductor material.

5. The transistor of claim 1, wherein the active layer comprises one or more layers of polymeric semiconductor.

6. The transistor of claim 1, wherein the active layer comprises one or more layers of a low molecular weight organic semiconductor.

7. The transistor of claim 1, wherein the active layer comprises one or more layers of a blend of an organic semiconductor and a polymer.

8. The transistor of claim 1, wherein the layer of interfacial conductive clusters comprises a predominantly non-carbon metallic material.

9. The transistor of claim 1, wherein a work function of the interfacial conductive clusters allows formation of an ohmic contact with the active layer.

10. The transistor of claim 1, wherein the layer of interfacial conductive clusters is configured to provide a wetting layer that improves contact between layers disposed on either side of the layer of interfacial conductive clusters.

11. A field effect transistor, comprising:
an active layer comprising a semiconductor material and carbon nanotubes;
gate, source, and drain contacts electrically coupled to the active layer;
a dielectric material arranged relative to the gate contact; and
a layer of discontinuous interfacial conductive material arranged between the dielectric material and the active layer.

12. The transistor of claim 11, wherein the layer of discontinuous interfacial conductive material is configured to provide a wetting layer that improves contact between layers disposed on either side of the layer of interfacial conductive material.

13. The transistor of claim 11, wherein the layer of discontinuous interfacial conductive material is disposed on a surface of the dielectric material.

14. The transistor of claim 11, wherein the active layer comprises one or more layers of a solution-based organic semiconductor material.

15. The transistor of claim 11, wherein a work function of the discontinuous interfacial conductive layer allows formation of an ohmic contact with the active layer.

16. A method for fabricating a field effect transistor having gate, source and drain contacts, the method comprising:
forming an active layer comprising a semiconductor;
forming a dielectric between the active layer and the gate contact; and
forming a layer of discontinuous interfacial conductive clusters between the dielectric and the active layer.

17. The method of claim 16, wherein:
forming the active layer comprises printing one or more of the active layer, the dielectric or the contacts; and
forming the layer of discontinuous interfacial conductive clusters comprises depositing or printing the layer of discontinuous interfacial conductive clusters on the dielectric.

18. The method of claim 16, wherein forming the discontinuous interfacial conductive layer comprises:
selecting a conductive material having a work function that forms an ohmic contact with the active layer; and
forming the discontinuous interfacial conductive layer using the selected conductive material.

19. The method of claim 16, wherein forming the active layer comprises forming the active layer using a solution-based organic semiconductor.

20. The method of claim 16, wherein forming the active layer comprises forming the active layer using an organic semiconductor and carbon nanotubes.
